(19) United States
(12) Patent Application Publication
(10) Pub. No.: US 2004/0060513 A1
(43) Pub. Date: Apr. 1, 2004

(54) Processing method and processing apparatus

(76) Inventors: Yasuhiko Kojima, Nirasaki-shi (JP); Susumu Arima, Nirasaki-shi (JP); Hideaki Yamasaki, Nirasaki-shi (JP); Yumiko Kawano, Nirasaki-shi (JP)

Correspondence Address: CROWELL & MORING LLP, INTELLECTUAL PROPERTY GROUP, P.O. BOX 14300, WASHINGTON, DC, 20044-4300, US

(21) Appl. No.: 10/433,095

(22) PCT Filed: Dec. 14, 2001
(86) PCT No.: PCT/JP01/10959

(30) Foreign Application Priority Data
Dec. 15, 2000 (JP) 2000-382201

(51) Int. Cl. H01L 21/68; C23C 16/00

(52) U.S. Cl. 118/715

(57) ABSTRACT

After a thin film is deposited on a treatment surface of a wafer and the wafer is transferred out of a treatment chamber, a contact projection of a clamp is brought into contact with a susceptor to heat the clamp. Next, a wafer is disposed on the susceptor by elevating the clamp when the wafer, on which a thin film is not deposited, is transferred in. Thereafter, the clamp is brought into contact with the wafer and the wafer is stabilized to a predetermined temperature. Thereafter, a thin film is deposited on a treatment surface of the wafer.

### TECHNICAL FIELD

The present invention relates to treatment of a substrate, in detail, to a processing method in that a substrate, such as a wafer, is disposed on a susceptor and heated, thereby treating the substrate, and a processing apparatus.

### PRIOR ART

So far, an apparatus for heat-treating a substrate, such as a silicon wafer (hereinafter, referred to as a wafer) or the like, comprises a treatment table, called a susceptor, and a resistance heating-element disposed inside the susceptor. In such a processing apparatus, after the resistance heating-element heats the susceptor up to a predetermined temperature, the wafer is disposed on the susceptor and heat-treated by heat from the susceptor.

FIG. 16 is a vertical sectional view schematically showing an existing processing apparatus.

As shown in FIG. 16, the existing processing apparatus 100 includes a susceptor 102, which allows a wafer W to be disposed in a chamber 101. In order to protect and uniformly treat the wafer W disposed on the susceptor 102, a thin and narrow annular member, called a clamp 103, is disposed on the susceptor 102. The clamp 103 is disposed elevatable with respect to a top surface of the susceptor 102, and covers and depresses a periphery of the wafer W disposed on the susceptor 102.

When the clamp 103 comes into contact with the periphery of the wafer W, since heat is deprived of a treatment surface of the wafer W, a temperature of the wafer W becomes uneven, resulting in a problem in that the treatment surface of the wafer W may not be uniformly treated.

To this end, there is proposed a processing apparatus in that, in a state where a wafer is disposed on the susceptor, before the wafer is treated, the clamp is heated through the wafer by means of the resistance heating-element disposed inside of the susceptor.

However, in this apparatus, since the clamp is heated through the wafer, heat is deprived of the periphery of the wafer. Accordingly there is a problem in that it takes a time to stabilize the wafer at a predetermined temperature. In particular, when the wafers are successively treated one at a time, since the temperature of the clamp comes down when the wafer W is transferred in and out, every time the wafer is disposed on the susceptor, the clamp has to be heated. As a result, there is a problem in that it may take a very long time.

### DISCLOSURE OF THE INVENTION

The present invention is carried out to overcome the aforementioned existing problems.

That is, the object of the present invention is to provide a processing method and a processing apparatus capable of shortening a treatment time necessary for treating a substrate.

In order to accomplish the above object, a processing method of the present invention includes transferring a first substrate into a treatment chamber and disposing the first substrate on a susceptor in the treatment chamber; holding the first substrate disposed on the susceptor by means of a clamp; applying treatment on the first substrate held by the clamp; separating the clamp from the treated first substrate; transferring out the first substrate from the treatment chamber; heating the clamp while the treated first substrate is transferred out of the treatment chamber and an untreated second substrate is transferred into the treatment chamber; transferring the second substrate into the treatment chamber and disposing the second substrate on the susceptor in the treatment chamber; holding the second substrate disposed on the susceptor by the clamp; and treating the second substrate held by the clamp. The first and second substrates are, respectively, at least one piece or more. The first substrate is not restricted to a first substrate to be treated. Since the present processing method includes heating the clamp while the first substrate is transferred out of the treatment chamber and the untreated second one is transferred into the treatment chamber, a treatment time of the second substrate may be shortened.

In the heating of the clamp in the aforementioned treatment method, a temperature of the clamp is detected by means of a temperature sensor, and the heating of the clamp is carried out based on the detected temperature of the clamp. Since the processing method of the present invention detects the temperature of the clamp by means of the temperature sensor and is carried out based on the detected temperature of the clamp, a time necessary for processing the second substrate may be shortened. Furthermore, since the clamp may be maintained at a predetermined temperature or more, the treatment may be uniformly applied on the second substrate.

The second substrate in the aforementioned processing method is one piece. Since the second substrate is one piece, treatment accuracy and reproducibility may be improved.

In the above processing method, the clamp is preferably heated by bringing the clamp into contact with the heated susceptor. Since the clamp is heated by bringing it into contact with the heated susceptor, a complicated structure is not necessary. As a result, a manufacturing cost may be suppressed from rising.

In the above processing method, the clamp is preferably heated by a heating lamp disposed outside the treatment chamber. Since the clamp is heated by the heating lamp disposed outside the treatment chamber, a temperature rise speed of the clamp may be expedited.

In the above processing method, the clamp is preferably heated until the clamp is maintained at temperatures of minus 30° C. or more with respect to a treatment temperature of the second substrate. Since the clamp is heated until the clamp is maintained at temperatures of minus 30° C. or more with respect to a treatment temperature of the second substrate, the clamp may be maintained at a predetermined temperature or more. As a result, the second substrate may be uniformly treated.

A processing apparatus of the present invention includes a treatment chamber; a susceptor, on which a substrate is disposed in the treatment chamber; an elevatable clamp for holding the substrate on the susceptor; a driver for elevating the clamp; a heater portion for heating the susceptor; a processing gas introducing system for introducing a processing gas into the treatment chamber; and a driver controller for controlling the driver so that the clamp may come into contact with the susceptor while a treated substrate is transferred out of the treatment chamber and an untreated substrate is transferred into the treatment chamber. Since the processing apparatus of the present invention is provided with the driver controller that controls the driver so that the clamp may come into contact with the susceptor while the treated substrate is transferred out of the treatment chamber and the untreated substrate is transferred into the treatment chamber, a treatment time necessary for treating the substrate may be shortened.

Another processing apparatus of the present invention includes a treatment chamber; a susceptor, on which a substrate is disposed in the treatment chamber; an elevatable clamp for holding the substrate on the susceptor; a driver for elevating the clamp; a heating lamp for heating the clamp, disposed outside of the treatment chamber; a processing gas introducing system for introducing the processing gas into the treatment chamber; and a heating lamp controller for controlling the heating lamp so that the clamp may be heated by the heating lamp while a treated substrate is transferred out of the treatment chamber and an untreated substrate is transferred into the treatment chamber. Since the processing apparatus of the present invention is provided with a heating lamp controller that controls the heating lamp so that the clamp may be heated by the heating lamp while the treated substrate is transferred out of the treatment chamber and the untreated substrate is transferred into the treatment chamber, the treatment time necessary for treating the substrate may be shortened. Furthermore, the temperature rise speed of the clamp may be expedited.

The aforementioned processing apparatus further includes a temperature sensor for detecting a temperature of a clamp: and a heater controller that controls the heater, based on the temperature of the clamp detected by the temperature sensor, while the treated substrate is transferred out of the treatment chamber and the untreated substrate is transferred into the treatment chamber. Since the processing apparatus is provided with the temperature sensor and the heater controller, the heater may be controlled based on the temperature of the clamp detected by the temperature sensor; and the clamp may be maintained at a predetermined temperature.

The aforementioned processing apparatus further includes a temperature sensor for detecting a temperature of a clamp: and a auxiliary driver controller that controls the driver based on the temperature of the clamp detected by the temperature sensor, while the treated substrate is transferred out of the treatment chamber and the untreated substrate is transferred into the treatment chamber. Since the processing apparatus is provided with the temperature sensor and the auxiliary driver controller, the clamp may be controlled in its height based on the detected temperature of the clamp; and the clamp may be maintained at a predetermined temperature.

### BRIEF EXPLANATION OF THE DRAWINGS

FIG. 1 is a vertical sectional view schematically showing a CVD apparatus according to a first implementation mode.

FIG. 2 is a schematic vertical sectional view showing in enlargement a clamp periphery portion according to the first implementation mode.

FIG. 3 is a plan view schematically showing the clamp according to the first implementation mode.

FIG. 4 is a vertical sectional view showing the clamp by cutting along an A-A line in FIG. 3.

FIG. 5 is a flowchart showing a flow of treatment carried out in the CVD apparatus according to the first implementation mode.

FIG. 6A to FIG. 6O are diagrams schematically showing a sequence of treatment carried out in the CVD apparatus according to the first implementation mode.

FIG. 7 is a graph showing relationship between temperature of the clamp and time in the CVD process according to the first implementation mode.

FIG. 8 is a vertical sectional view schematically showing a CVD apparatus according to a second implementation mode.

FIG. 9 is a flowchart showing a flow of treatment carried out in the CVD apparatus according to the second implementation mode.

FIG. 10 is a vertical sectional view schematically showing a CVD apparatus according to a third implementation mode.

FIG. 11 is a flowchart showing a flow of treatment carried out in the CVD apparatus according to the third implementation mode.

FIG. 12A to FIG. 12C are diagrams schematically showing a sequence of treatment carried out in the CVD apparatus according to the third implementation mode.

FIG. 13 is a schematic vertical sectional view showing in enlargement a clamp periphery according to the fourth implementation mode.

FIG. 14 is a vertical sectional view schematically showing a CVD apparatus according to a fifth implementation mode.

FIG. 15 is a vertical sectional view schematically showing a CVD apparatus according to a sixth implementation mode.

FIG. 16 is a vertical sectional view schematically showing an existing processing apparatus.

### BEST MODES FOR IMPLEMENTING THE PRESENT INVENTION

(The First Implementation Mode)

In the following, a processing method and a processing apparatus according to the first implementation mode of the present invention will be explained.

In the present implementation mode, as a processing apparatus, a CVD apparatus (Chemical vapor Deposition), by means of which a thin film is chemically deposited on a treatment surface of, for instance, a wafer as a substrate, will be explained.

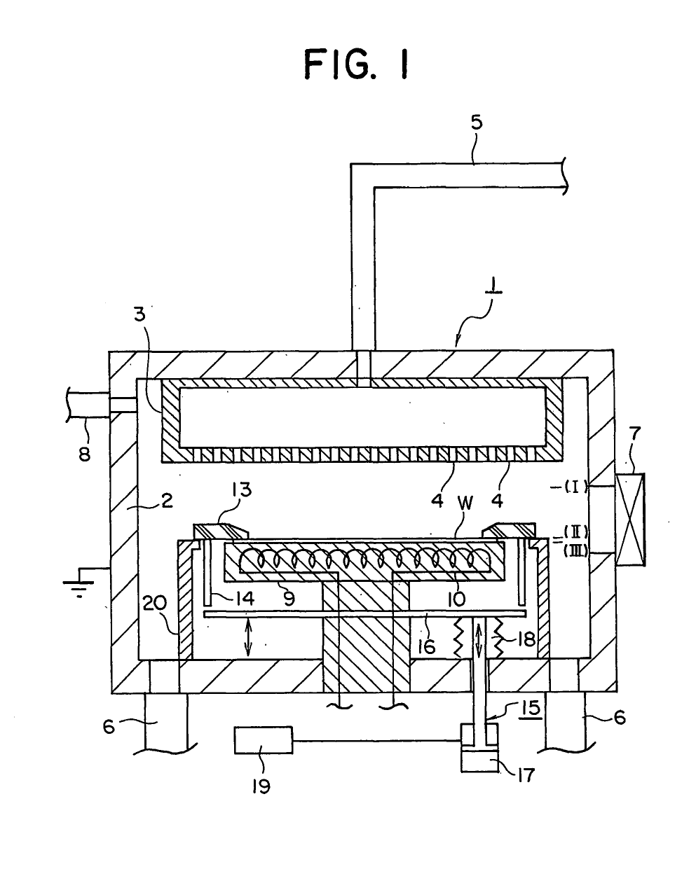

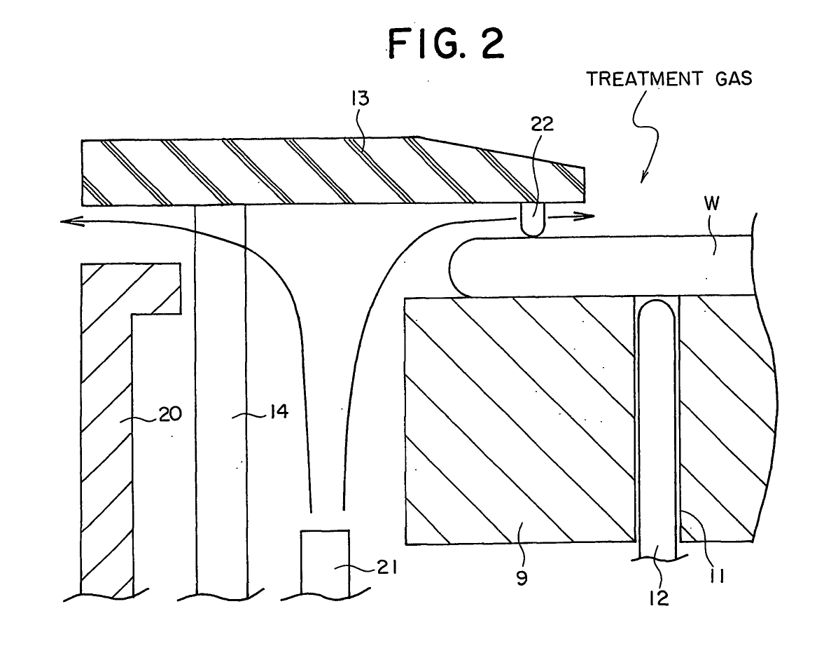

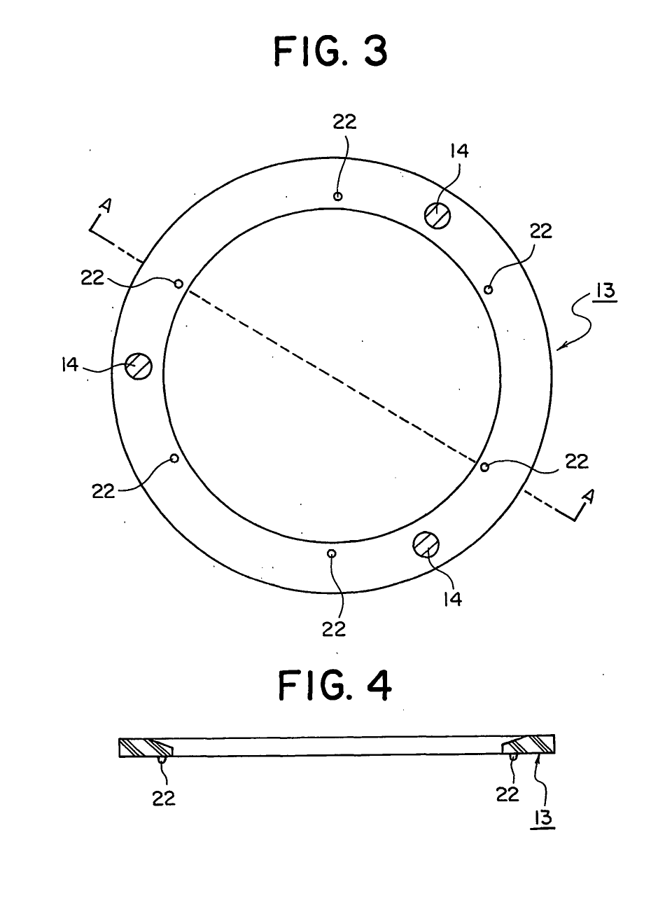

FIG. 1 is a vertical sectional view schematically showing a CVD apparatus according to the present implementation mode; FIG. 2 is a schematic vertical sectional view showing in enlargement a clamp periphery according to the present implementation mode; FIG. 3 is a plan view schematically showing the clamp according to the present implementation mode; and FIG. 4 is a vertical sectional view showing the clamp by cutting along an A-A line in FIG. 3.

As shown in FIG. 1 to FIG. 4, a CVD processing apparatus 1 includes a treatment chamber 2 formed, in a substantial cylinder, of, for instance, aluminum or stainless steel. The treatment chamber 2 is grounded.

On a ceiling of the treatment chamber 2, a showerhead 3 for supplying a processing gas into the treatment chamber 2 is disposed so as to face a susceptor 9 described below. By supplying the processing gas from the showerhead 3, a thin film of, for instance, copper or titanium nitride, is deposited on a treatment surface of the wafer W.

The showerhead 3 is formed in a hollow structure and at a bottom thereof 3, a plurality of discharge openings 4 is formed. By forming the plurality of openings 4, the processing gas, which is introduced into the showerhead 3 and diffused there, is ejected into a space between the bottom surface of the showerhead 3 and the susceptor 9 described below.

At an upper portion of the showerhead 3, a processing gas conduit 5 for introducing the processing gas is attached. A not shown treatment agent tank for reserving a liquid treatment agent is connected, through not shown liquid mass flow controller, valve, and evaporator, to the processing gas conduit 5. The valve, in an open state, controls a flow rate of the treatment agent by means of the mass flow controller; and the evaporator converts the liquid treatment agent into a gaseous processing gas and thereby a predetermined amount of the processing gas is supplied into the treatment chamber 2.

On the bottom of the treatment chamber 2, an exhaust pipe 6 connected to a not shown vacuum pump is disposed. Due to the operation of the not shown exhaust pump, the inside of the treatment chamber 2 is evacuated through the exhaust pipe 6.

An opening is formed on a sidewall of the treatment chamber 2, and in the neighborhood of the opening, a gate valve 7 is disposed to transfer in and out the wafer W. Furthermore, a purge gas supply pipe 8 is connected to the sidewall of the treatment chamber 2 to supply a purge gas, such as, for instance, a nitrogen gas.

At a position facing to the showerhead 3 in the treatment chamber 2, a substantially disc-like susceptor 9 is disposed to dispose the wafer W. The susceptor 9 is made of, for instance, aluminum nitride, silicon nitride, aluminum, or stainless steel. The susceptor 9 is inserted into the treatment chamber 2 through an opening formed at a bottom center of the treatment chamber 2.

A resistance heating-element 10, as a heater portion, is disposed inside of the susceptor 9 to heat the susceptor 9 and maintain the susceptor 9 at a definite temperature. Furthermore, lifter openings 11 are formed in an up and down direction at positions equally divided into, for instance, three of a circumference of the susceptor 9. Three elevatable lifter pins 12 are inserted in each of the lifter openings 11. By the elevation of the lifter pins 12, the wafer W is disposed on the susceptor 9 or separated from on the susceptor 9.

An annular clamp 13, which comes into contact with a periphery of a treatment surface of the wafer W, is disposed at the periphery of a top surface of the susceptor 9. Support pins 14 are substantially vertically connected to positions equally divided into three of the bottom surface side of the clamp 13 to support the clamp 13. An elevator 15, as a driver for elevating the clamp 13, is disposed downwards of the support pins 14. The elevator 15 is substantially constituted of a top plate 16, which is disposed immediately under the support pins 14 and pushes up the support pins 14, and a cylinder 17, which is expandable in an up and down direction in which the top plate 16 is elevated. When the cylinder 17 drives so as to elevate the top plate 16, the support pins 14 are pushed up, and the clamp 13 is elevated. Furthermore, when the cylinder 17 drives so as to lower the top plate 16, the clamp 13 descends due to the clamp's 13 own weight.

A portion of the cylinder 17 from a bottom inside wall side of the treatment chamber 2 up to the top plate 16 is covered by an expandable metal bellows 18. By partially covering the cylinder 17 by means of the bellows 18, air-tightness inside of the treatment chamber 2 may be maintained.

An elevator controller 19, as the driver controller for controlling drive of the cylinder 17, is electrically connected to the cylinder 17. The elevator controller 19 controls the drive of the cylinder 17 so that the clamp 13 may stop at a wafer transfer position (I) for transferring the wafer W into and out of the treatment chamber 2, a wafer processing position (II) for depositing a thin film on a treatment surface of the wafer W, and a clamp heating position (III) for heating the clamp 13. The wafer transfer position (I) is located at, for instance, substantially 10 mm above the surface of the susceptor 8.

Outside the clamp 13, a cylindrical shield plate 20 is disposed so that the susceptor 9 may be positioned inside thereof. The shield plate 20 is disposed so that it may be at a substantially equal height with the top surface of the susceptor 9.

An inert gas supply pipe 21, which supplies the inert gas, such as, for instance, an argon gas, from the bottom of the treatment chamber 2 towards an upper portion thereof, is connected to the bottom of the treatment chamber 2 more inside than the shield plate 20. By supplying the inert gas from the inert gas supply pipe 21, an air curtain, described below, of the inert gas is formed between the susceptor 9 and the clamp 13.

Next, the clamp 13 will be explained.

The clamp 13 is formed of ceramics substantially made of, for instance, aluminum nitride, alumina, or silicon carbide. The clamp 13 is formed in a thickness that does not take a long time to stabilize a temperature. Specifically, the clamp 13 is formed in a thickness of, for instance, from 1 to 3 mm, preferably in a thickness of from 1.5 to 3 mm. The reason for the clamp 13 being formed in the thickness of from 1 to 3 mm is as follows. When the thickness is less than 1 mm, there are problems in that machining is difficult, and due to heating, warping occurs; when it exceeds 3 mm, it takes a long time to stabilize the temperature of the clamp 13.

The clamp 13 comes into contact with the periphery of the wafer W due to its 13 own weight, when a thin film is formed on the treatment surface of the wafer W. At this time, the wafer W is depressed by the clamp 13. By coming into contact with the periphery of the wafer W due to its 13 own weight, even when the wafer W is treated one at a time, weight on the periphery of the treatment surface of the wafer W does not vary every treatment. Accordingly, thickness variation of the wafer W at every treatment may be suppressed from occurring.

On a bottom face side of the clamp 13, contact projections 22 are formed at positions of the circumference equally divided into, for instance, six. A height of the contact projection 22 is, for instance, substantially 100 μm. When the clamp 13 comes into contact with the wafer W, only the contact projection 22 comes into contact with the treatment surface of the wafer W. By allowing the contact projection 22 only to come into contact with the treatment surface of the wafer W, the thin film is assuredly hindered from depositing on a side surface and back surface of the wafer W. That is, when the inert gas is supplied from the inert gas supply pipe 21, the inert gas rises past between the side surface of the susceptor 9 and the shield plate 20 up to the clamp 13. The inert gas gone up to the clamp 13 collides with the bottom face of the clamp 13 and is divided into two flows, one directing towards a center from the periphery portion of the wafer W and the other directing towards outside of the shield plate 20. Since the inert gas directing from the periphery portion of the wafer W towards the center forms an air curtain between the susceptor 9 and the clamp 13, the processing gas supplied from the showerhead 3 is assuredly hindered from going around the side surface and back surface of the wafer W. Accordingly, thin film is assuredly hindered from depositing on the side surface and back surface of the wafer W.

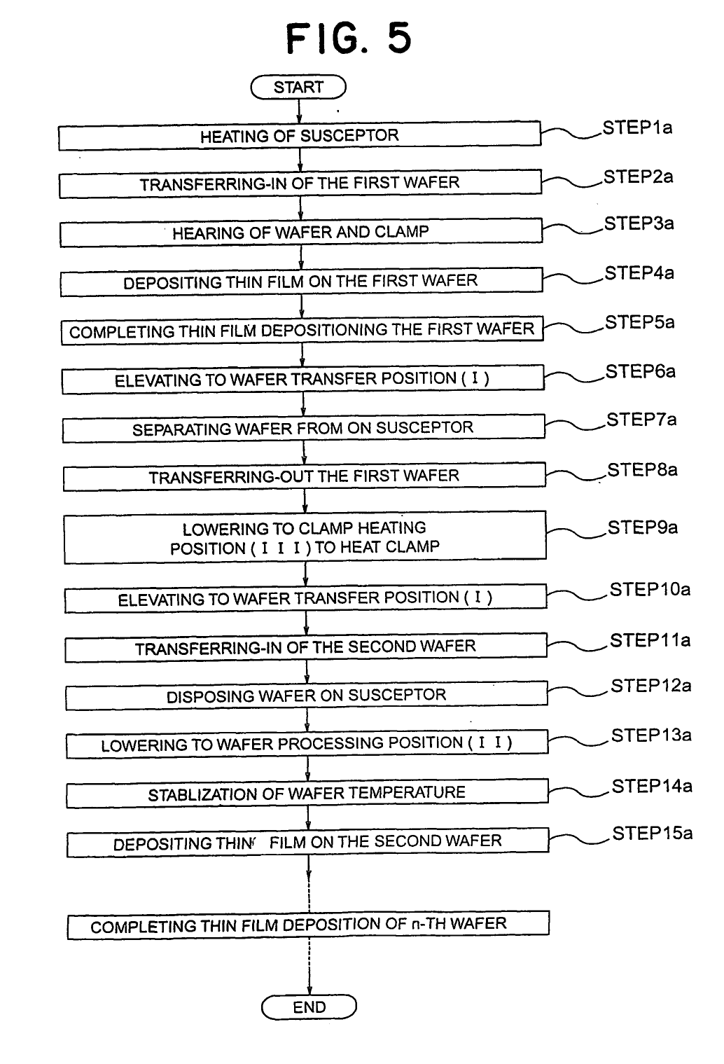

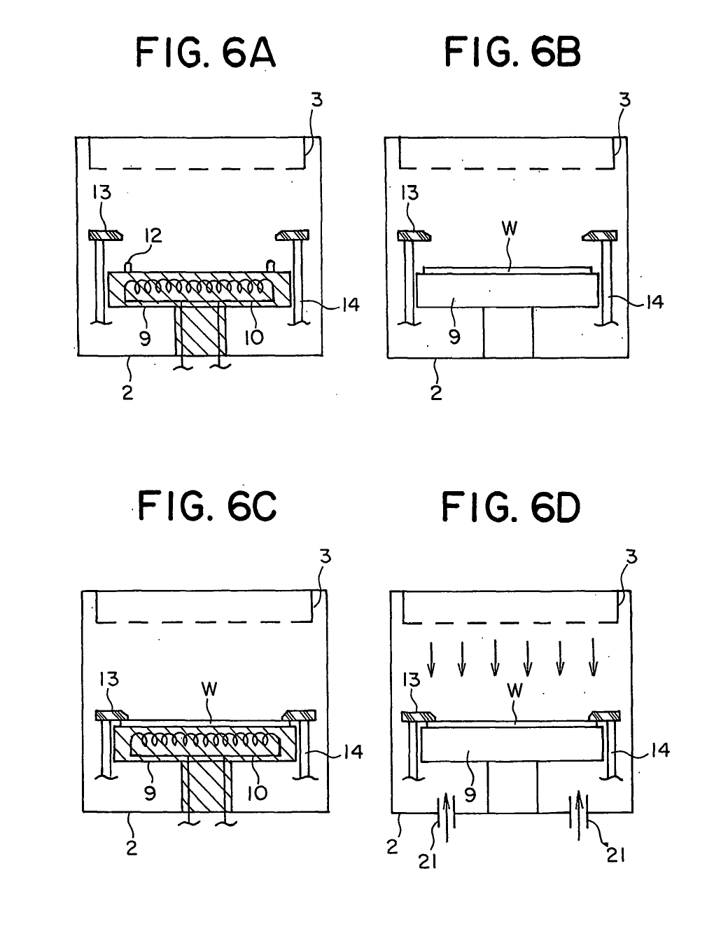

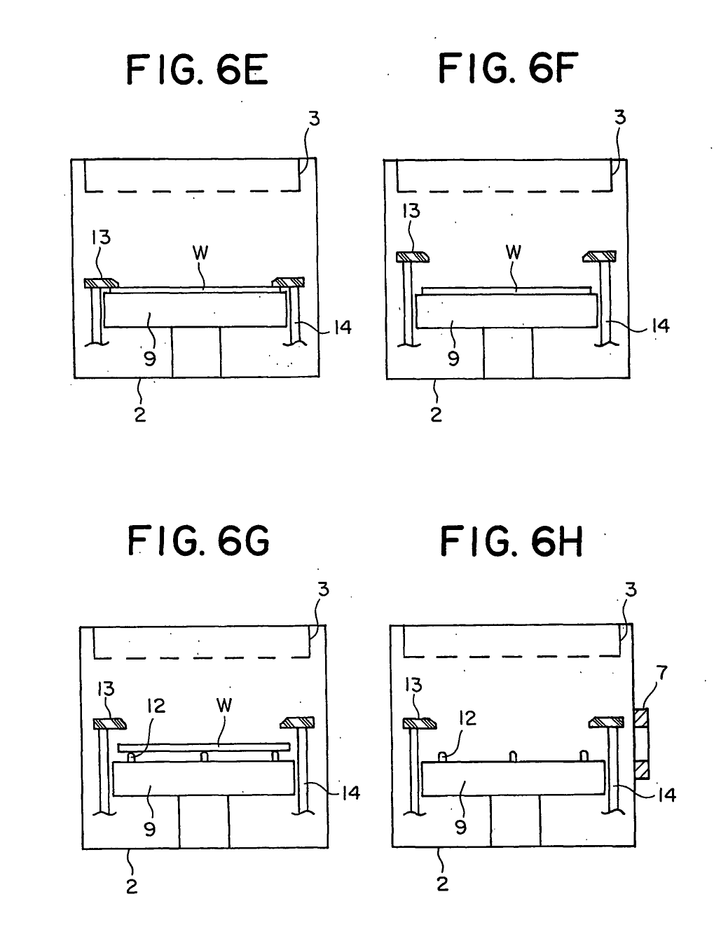

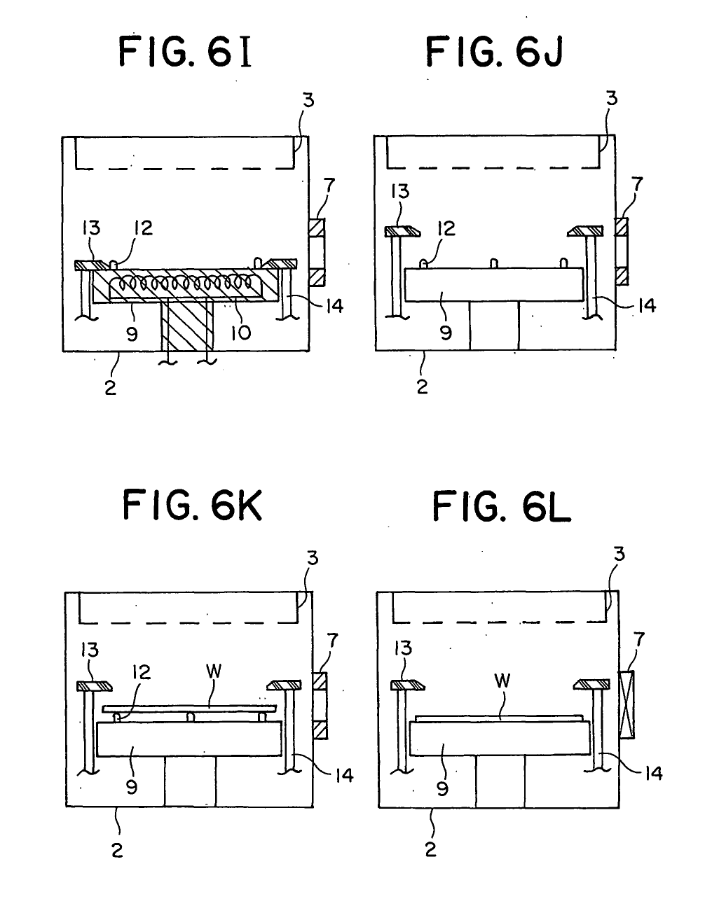

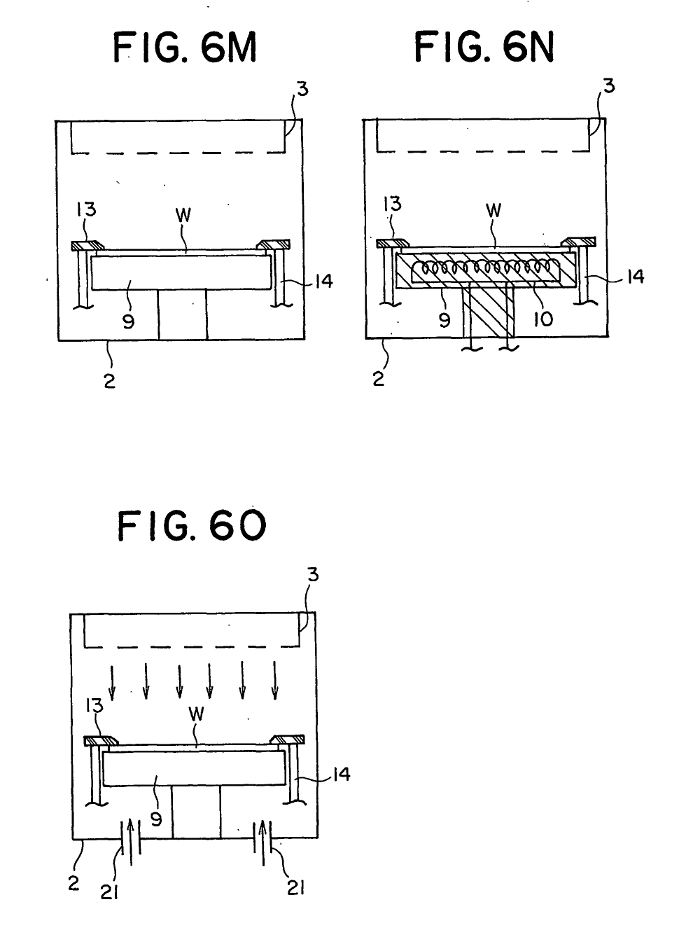

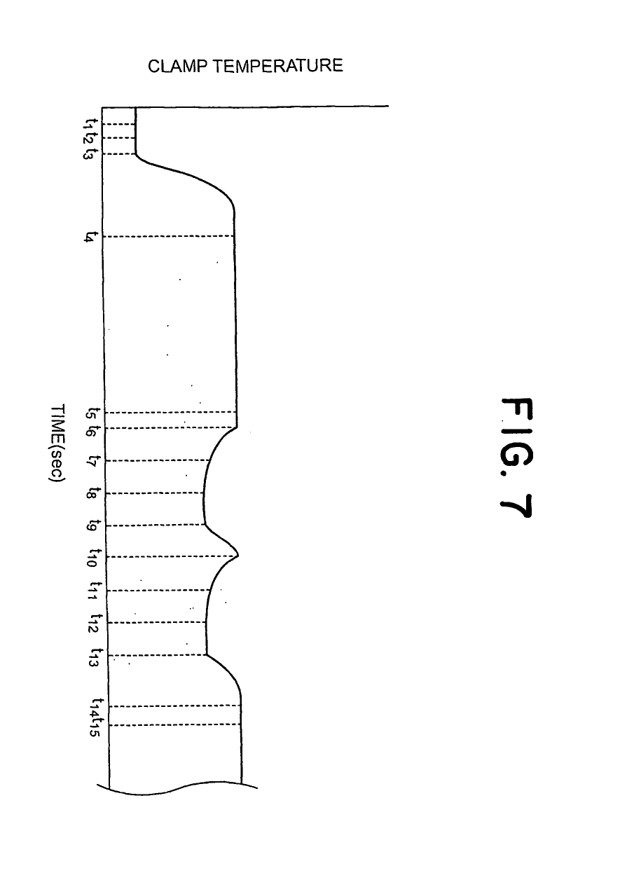

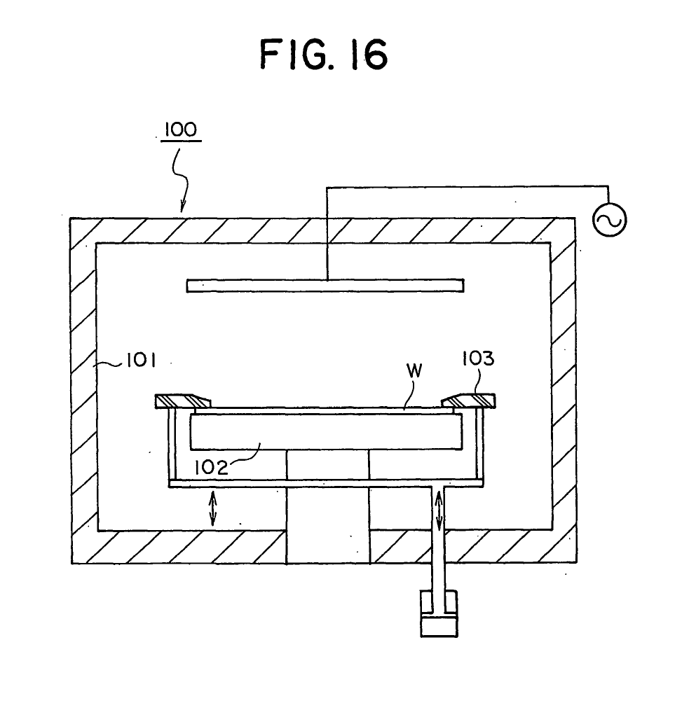

In the following, a sequence of flow of treatment in the CVD apparatus 1 according to the present implementation mode will be explained along FIG. 5 to FIG. 7. FIG. 5 is a flowchart showing a sequence of flow of treatment carried out in the CVD apparatus 1 according to the present implementation mode, FIG. 6A to FIG. 60 are diagrams schematically showing treatment steps carried out in the CVD apparatus 1 according to the present implementation mode, and FIG. 7 is a graph showing relationship between clamp temperature and time of the CVD treatment step according to the present implementation mode.

The CVD treatment of the wafers according to the present implementation mode will be explained of a case where n wafers are successively treated one at a time. First, in a state where a power source of the CVD apparatus 1 is turned on, a voltage is input to a resistance heating-element 10, and, as shown in FIG. 6A, at time t₁, the susceptor 9 is heated to a predetermined temperature (step 1a).

The gate valve 7 is opened after the susceptor 9 is heated to a predetermined temperature, and a not shown transfer arm extends to transfer a first untreated wafer W into the treatment chamber 2. The wafer W transferred into the treatment chamber 2 is disposed on the elevated lifter pins 12 by means of the not shown transfer arm. Thereafter, as shown in FIG. 6B, the lifter pins 12 descends and the wafer W is disposed on the susceptor 9, at time t₂ (step 2a).

Next, the elevator controller 19 controls the drive of the cylinder 17 so that, as shown in FIG. 6C, the clamp 13 maybe lowered from the wafer transfer position (I) to the wafer processing position (II), thereby the contact projections 22 may come into contact with the treatment surface of the wafer W. After the contact projections 22 come into contact with the treatment surface of the wafer W, the wafer W and the clamp 13 are heated, at time t₃, by means of the resistance heating-element 10 inside of the susceptor 9, to a predetermined temperature (step 3a).

After the wafer W and the clamp 13 are heated and stabilized at a predetermined temperature, the treatment chamber 2 is evacuated by a not shown vacuum pump. Furthermore, the processing gas and the inert gas are supplied into the treatment chamber 2, and, thereby, as shown in FIG. 6D, a thin film is deposited on the treatment surface of the first wafer W, at time t₄ (step 4a).

After the thin film is deposited with a predetermined thickness on the treatment surface of the first wafer W, as shown in FIG. 6E, the processing gas supply is stopped at time t₅, thereby the thin film deposition comes to completion (step 5a).

After the completion of the thin film formation, the elevator controller 19 controls the drive of the cylinder 17 so that, as shown in FIG. 5F, the clamp 13 may be elevated from the wafer processing position (II) to the wafer transfer position (I), at time t₆ (step 6a).

After the clamp 13 is elevated to the wafer transfer position (I), as shown in FIG. 6G, the lifter pins 12 are elevated at time t₇, and the wafer W is separated from on the susceptor 9 (step 7a).

After the wafer W is separated, at the same time with the opening of the gate valve 7, the not shown transfer arm extends into the treatment chamber 2 and, as shown in FIG. 6H, transfers the first wafer W, on which the thin film is formed, out of the treatment chamber 2, at time t₈ (step 8a).

After the first wafer W, on which the thin film is formed, is transferred out of the treatment chamber 2, the elevator controller 19 controls the drive of the cylinder 17 so that, as shown in FIG. 6I, the clamp 13 may be lowered from the wafer transfer position (I) to the clamp heating position (III), at time t₉. When the clamp 13 is lowered to the clamp heating position (III), the contact projections 22 of the clamp 13 come into contact with the susceptor 9. Since the resistance heating-element 10 is disposed inside the susceptor 9, the susceptor 9 may be heated to a predetermined temperature. The heating due to the resistance heating-element 10 is implemented not only during the thin film deposition but also when the clamp 13 is positioned at the clamp heating position (III). Accordingly, the contact projections 22, which are in contact with the susceptor 9, of the clamp 13, are heated by means of the resistance heating-element 10, thereby an entire clamp 13 is heated (step 9a).

The clamp 13 is heated until a temperature, which does not adversely affect during the thin film deposition, or more is reached and maintained. specifically, the clamp 13 is heated until a temperature, which is lower by 30° C. with respect to, for instance, a thin film deposition temperature of the wafer W, or more is reached and maintained there. The reason for the temperature of the clamp 13 being set at the aforementioned numerical value or more is as follows. That is, when the temperature of the clamp 13 is lower than the aforementioned numerical value during the thin film deposition, a deposition speed in the neighborhood of the periphery of the wafer W decreases. Accordingly, the thin film may not be deposited uniformly on the treatment surface of the wafer W.

Furthermore, since the clamp 13 is heated by bringing it into contact with the susceptor 9, a structure of the CVD apparatus is not complicated; and the manufacturing costs are not caused to go up. In addition, maintenance operation does not invite inconvenience.

After the clamp 13 is heated up to the aforementioned temperature, the elevator controller 19 controls the drive of the cylinder 17 so that, as shown in FIG. 6J, the clamp 13 may be elevated from the clamp heating position (III) to the wafer transfer position (I), at time t₁₀ (step 10a).

After the clamp 13 is elevated, a second wafer W, on which a thin film is not deposited, is transferred into the treatment chamber 2 by means of the not shown transfer arm, and, as shown in FIG. 6K, the wafer W is disposed on the elevated lifter pins 12 at time t₁₁ (step 11a).

Since the clamp 13 is heated between the time t₈, at which time the first wafer W is transferred out, and the time t₁₁, at which time the second wafer W is transferred in, a time necessary for treating the wafer W may be shortened. That is, the clamp 13 is heated while the first wafer W, on which the thin film has been deposited, is transferred out of the treatment chamber 2 and accommodated into a not shown carrier cassette by means of the not shown transfer arm, and the second wafer W, on which a thin film is not deposited and which is accommodated in another carrier cassette, is taken out and transferred into the treatment chamber 2 by means of the transfer arm. As a result, since a particular time is not required for heating the clamp 13, the treatment time of the wafer W may be shortened.

After the wafer W is disposed on the lifter pins 12, the gate valve 7 is closed, and, as shown in FIG. 6L, the lifter pins 12 are lowered at time t₁₂, and the second wafer W is disposed on the susceptor 9 (step 12a).

After the wafer W is disposed on the susceptor 9, the elevator controller 19 controls the drive of the cylinder 17 so that, as shown in FIG. 6M, the clamp 13 may be lowered from the wafer transfer position (I) to the wafer processing position (II) at time t₁₃ (step 13a). The treatment surface of the wafer W is contacted only by the contact projections 22 of the clamp 13.

After the clamp 13 is lowered to the wafer processing position (II), as shown in FIG. 6N, the wafer W disposed on the susceptor 9 is heated to the thin film deposition temperature, for instance, 150° C., by means of the resistance heating-element 10 (step 14a).

In order to uniformly deposit the thin film on the treatment surface of the wafer W, the temperature of the entire wafer W has to be stabilized at the thin film deposition temperature. Accordingly, the temperature of the wafer W is stabilized at time t₁₄. Since the clamp 13, which is in contact with the treatment surface of the wafer W, has been heated to a predetermined temperature before the wafer W is transferred in, the time necessary for stabilizing the temperature of the entire wafer W may be shortened.

That is, while the first wafer W, on which the thin film has been deposited, is transferred out of the treatment chamber 2 and the second wafer W, on which the thin film is not deposited, is transferred into the treatment chamber 2, the clamp 13 is heated to the predetermined temperature. Accordingly, when the clamp 13 comes into contact with the wafer W, the periphery of the wafer W is not substantially deprived of the heat by the clamp 13. As a result, since the periphery of the wafer W shows only a little temperature decrease, the time necessary for stabilizing the temperature of the wafer W may be shortened.

After the temperature of the wafer W is stabilized, the treatment chamber 2 is evacuated by means of the not shown vacuum pump. In addition, as shown in FIG. 6O, the processing gas is supplied from the showerhead 3 and the inert gas is supplied from the inert gas supply pipe 21, thereby a thin film is deposited on the treatment surface of the second wafer W at time t₁₅ (step 15a).

Thereafter, by repeating the aforementioned steps ((step 5a) to (step 15a)), the thin films are successively deposited on the treatment surfaces of n pieces of the wafer W one at a time.

Thus, in the CVD apparatus 1 according to the present implementation mode, while the wafer W, on which the thin film is deposited, transferred out and the wafer W, on which the thin film is not deposited, is transferred in, the clamp 13 is heated. Accordingly, the time necessary for the entire CVD treatment including the thin film deposition, the wafer W transfer, and the heating of the wafer W may be shortened.

That is, while the (n−1)-th wafer W, on which the thin film has been deposited, is transferred out and the n-th wafer W, on which the thin film is not deposited, is transferred in, specifically between the time t₉ and time t₁₀, the clamp 13 is lowered to the clamp heating position (III) and heated. Accordingly, when the clamp 13 comes into contact with the wafer W, the periphery of the wafer W is hardly deprived of the heat by the clamp 13. As a result, since the temperature of the periphery of the wafer W decreases less, the time necessary for stabilizing the temperature of the wafer W may be shortened. As a result, the time necessary for the entire CVD treatment may be shortened.

In case the time necessary for stabilizing the temperature of the wafer W is set at a time the same as the existing one, since the temperature of the wafer W is furthermore stabilized, as a result, yield of the CVD treatment may be improved. Furthermore, since the wafer W is deposited one at a time, accuracy and reproducibility of the deposition may be improved.

(Embodiment 1)

In the following, embodiments of the present invention will be explained.

By use of the CVD apparatus explained in the aforementioned implementation mode, the time until the temperature of the wafer stabilizes is measured.

In the following, measurement conditions will be explained.

First, the processing gas and the inert gas are supplied into the treatment chamber of the CVD apparatus for 1 min, thereby a copper thin film is deposited on the treatment surface of the wafer disposed on the susceptor. As the treatment agent, one that contains Cu⁺¹ (hexafluoroacetylacetonate) and trimethyl vinyl silane (TMVS) is used. Furthermore, as the inert gas, an argon gas is employed.

Next, by means of the transfer arm, the wafer, on which the copper thin film has been deposited, is transferred out of the treatment chamber, and the wafer, on which the copper thin film is not deposited, is transferred therein. For 1 min during the above operations, the clamp is lowered to the clamp heating position (III) and heated to a temperature of 150° C.

Thereafter, the clamp is elevated to the wafer transfer position (I); the wafer, on which the copper thin film is not deposited, is disposed; the clamp is lowered to the wafer processing position (II); and thereafter the wafer is heated to a temperature of 150° C. In this state, the time until the temperature of the wafer stabilizes is measured.

In the following, measurement results will be described.

In the existing CVD apparatus, it takes substantially 1 min until the temperature of the wafer stabilizes. In comparison with this, in the CVD apparatus according to the present embodiment, it takes only substantially 15 sec until the temperature of the wafer stabilizes. Furthermore, in case 25 pieces of the wafers are successively treated, it is shortened by substantially 18 min than in the existing case. Accordingly, it is confirmed that the CVD apparatus according to the present embodiment takes a shorter time for stabilizing the temperature of the wafer than the existing CVD apparatus does.

(Second Implementation Mode)

In the following, a second implementation mode of the present invention will be explained. In the following implementation modes, contents duplicating the foregoing implementation mode may be in some cases omitted from explaining.

In the present implementation mode, an example, where the temperature of the clamp is measured when the clamp is heated, and an input voltage of the resistance heating-element in the susceptor is controlled base on the detected temperature, will be explained.

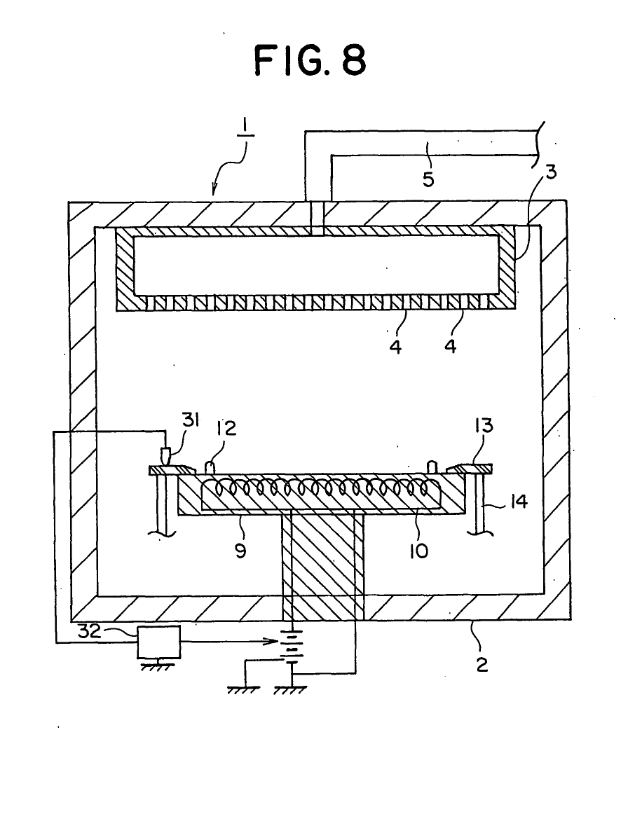

FIG. 8 is a vertical sectional view schematically showing a CVD apparatus according to the present implementation mode.

As shown in FIG. 8, a temperature sensor 31 is connected to the clamp 13; the temperature of the clamp 13 is detected thereby; and the detected temperature is converted into an electrical signal. The resistance heating-element 10 inside of the susceptor 9 is electrically connected to a resistance heating-element controller 32, as a heating controller, for controlling an input voltage of the resistance heating-element 10. By controlling the input voltage of the resistance heating-element 10 by means of the resistance heating-element controller 32, a heat generation amount of the resistance heating-element 10 may be controlled. The temperature sensor 31 and the resistance heating-element controller 32 are electrically connected; the resistance heating-element controller 32 controls the heat generation amount of the resistance heating-element 10 on the basis of the electrical signal output from the temperature sensor 31.

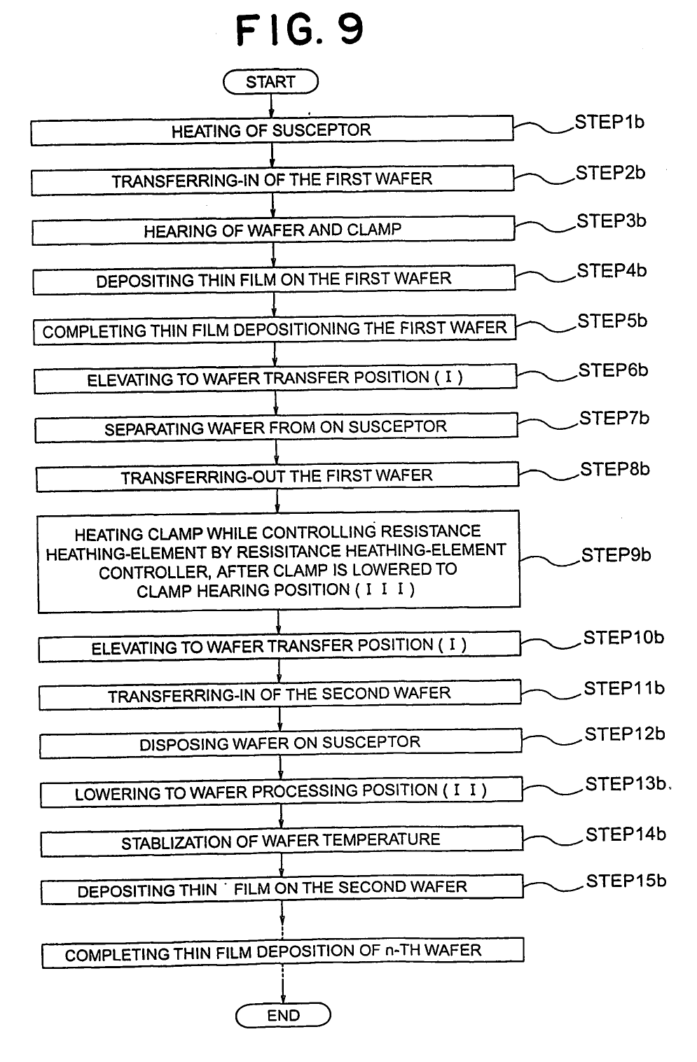

In the following, a flow of the treatment in the CVD apparatus 1 according to the present implementation mode will be explained with reference to FIG. 9. FIG. 9 is a flowchart showing a flow of the treatment carried out in the CVD apparatus 1 according to the present implementation mode.

First, after a first wafer W is transferred in and predetermined operations are carried out, a thin film is deposited on the first wafer W ((step 1b) to (step 5b)). After the thin film is deposited on the first wafer W, predetermined operations are carried out and the first wafer W, on which the thin film has been deposited, is transferred out of the treatment chamber 2 ((step 6b) to (step 8b)).

After the first wafer W, on which the thin film has been deposited, is transferred out of the treatment chamber 2, the elevator controller 19 controls the drive of the cylinder 17 so that the clamp 13 may be lowered from the wafer transfer position (I) to the clamp heating position (III). The clamp 13, which is lowered to the clamp heating position (III), comes into contact with the susceptor 9 and is heated thereby.

When the clamp 13 is heated, the temperature sensor 31, which is brought into contact with the clamp 13, detects the temperature of the clamp 13. The temperature detected by the temperature sensor 31 is converted into the electrical signal and is sent to the resistance heating-element controller 32, which controls the input voltage of the resistance heating-element 10. Since the resistance heating-element controller 32 is designed so that it may conceive that the temperature of the clamp 13 has risen to the predetermined temperature or more through the electrical signal from the temperature sensor 31, in case the clamp 13 has been heated to the predetermined temperature or more, the input voltage of the resistance heating-element 10 is made smaller. As a result, the heat generation amount of the resistance heating-element 10 becomes smaller; the temperature of the clamp 13 descends to the predetermined temperature. In case the temperature of the clamp 13 descends lower than the predetermined temperature, the input voltage of the resistance heating-element 10 is made larger again. As a result, the heat generation amount of the resistance heating-element 10 becomes larger; the temperature of the clamp 13 again reaches the predetermined temperature.

The aforementioned operations are repeated, and thereby the clamp 13 may be maintained at the predetermined temperature (step 9b). After the clamp 13 is heated up to the predetermined temperature, the predetermined operations are carried out; the second wafer W, on which the thin film is not deposited, is transferred into the treatment chamber 2; and a thin film is deposited on the wafer W ((step 10b) to (step 15b)).

Thereafter, the steps mentioned above ((step 5b) to (step 15b)) are repeated; thin films are successively deposited one at a time on the treatment surfaces of n pieces, in total, of the wafers W.

Thus, in the present implementation mode, since the temperature sensor 31 is connected to the clamp 13; the temperature of the clamp 13 is detected thereby; and, on the basis of the detected temperature, the input voltage of the resistance heating-element 10 is controlled, the clamp 13 may be maintained at the predetermined temperature.

(Third Implementation Mode)

In the following, the third implementation mode of the present invention will be explained.

In the present implementation mode, an example, where the temperature of the clamp is detected during the heating of the clamp; and on the basis of the detected temperature, the clamp is separated from the susceptor or brought into contact therewith, will be explained.

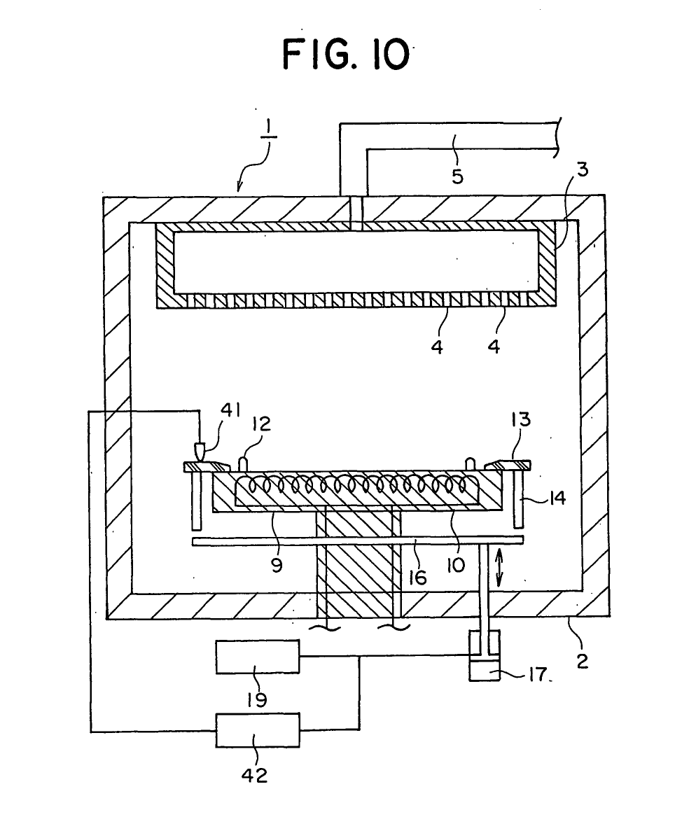

FIG. 10 is vertical sectional view schematically showing the CVD apparatus 1 according to the present implementation mode.

As shown in FIG. 10, a temperature sensor 41 is connected to the clamp 9, detects the temperature of the clamp 9, and converts it into an electrical signal. An auxiliary elevator controller 42, as the auxiliary driver controller, is connected to the temperature sensor 41 and the cylinder 17. The auxiliary elevator controller 42 controls the drive of the cylinder 17 based on the electrical signal transferred from the temperature sensor 41.

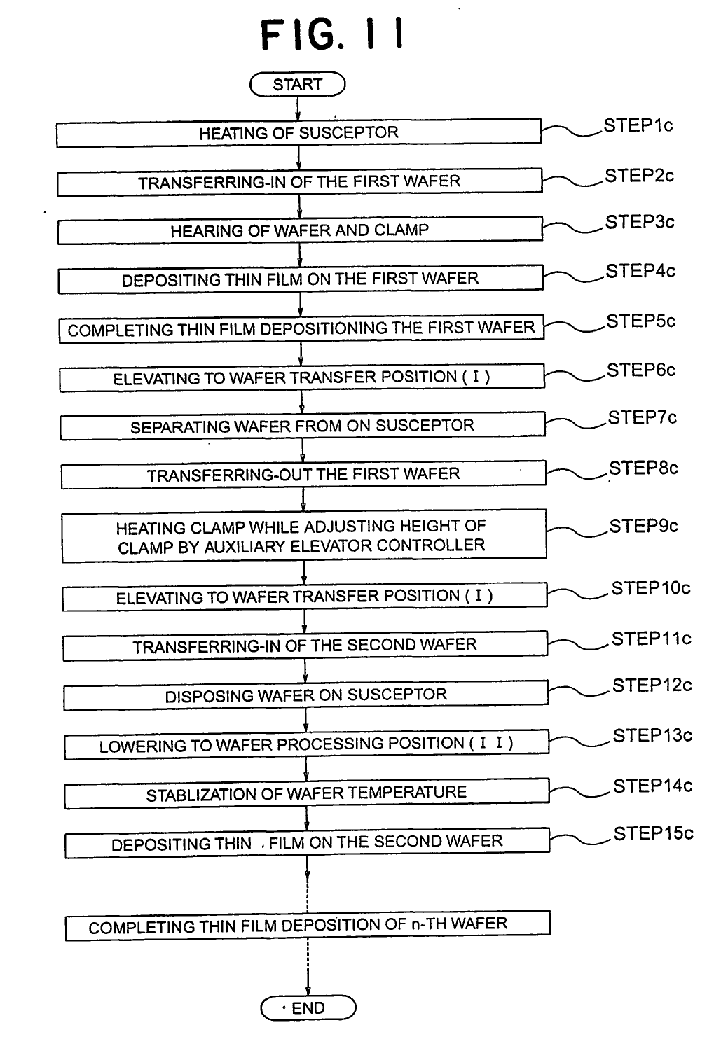

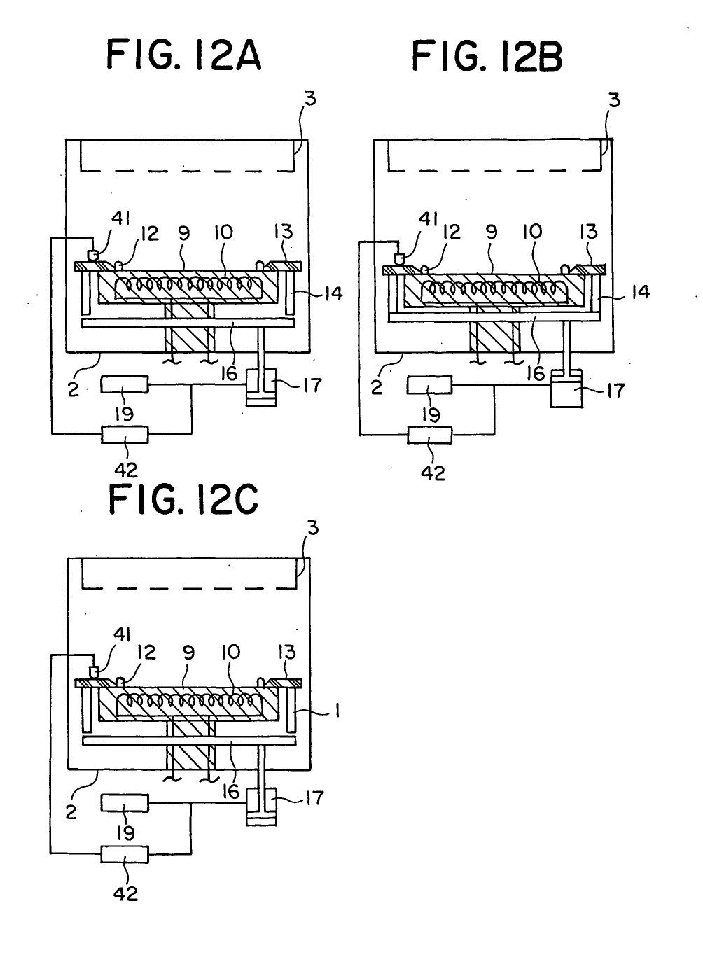

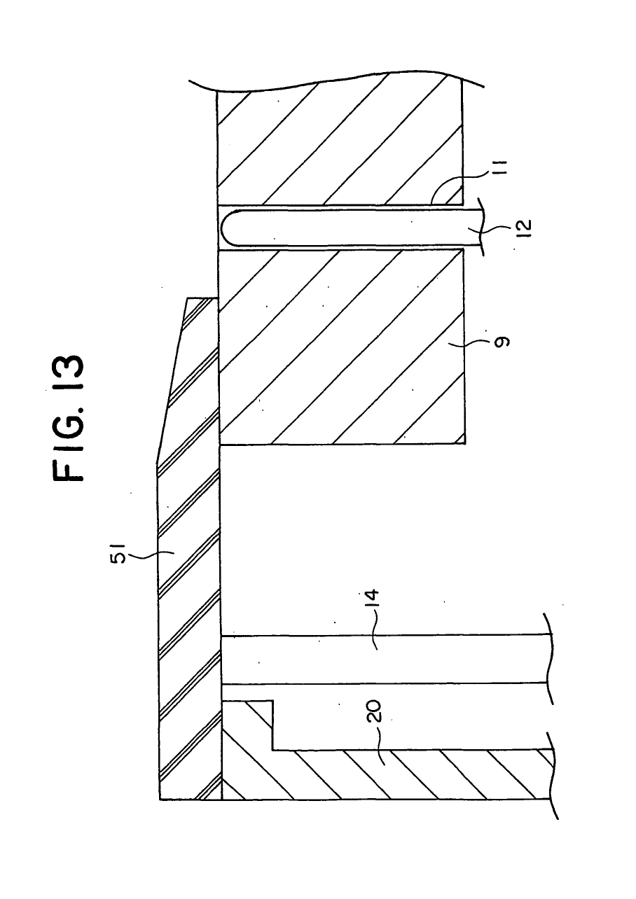

In the following, a treatment flow in the CVD apparatus 1 according to the present implementation mode will be explained with reference to FIG. 11 and FIG. 12. FIG. 11 is a flowchart showing a flow of treatment carried out in the CVD apparatus 1 according to the present implementation mode, FIG. 12A to FIG. 12C are diagrams schematically showing steps of the treatment carried out in the CVD apparatus 1 according to the present implementation mode.

First, after a first wafer W is transferred in and the predetermined operations are carried out, a thin film is deposited on the wafer W ((step 1c) to (step 5c)). After the thin film has been deposited on the first wafer W, the predetermined operations are carried out; the first wafer W, on which the thin film is deposited, is transferred out of the treatment chamber 2 ((step 6c) to (step 8c)).

After the first wafer W, on which the thin film has been deposited, is transferred out of the treatment chamber 2, the elevator controller 19 controls the drive of the cylinder 17 so that, as shown in FIG. 12A, the clamp 13 may be lowered from the wafer transfer position (I) to the clamp heating position (III). The clamp 13 lowered to the clamp heating position (III) comes into contact with the susceptor 9 and is heated.

During the heating of the clamp 13, the temperature of the clamp 13 is detected by means of the temperature sensor 41 connected to the clamp 13. The temperature, which is detected y the temperature sensor 41, is converted into the electrical signal and sent to the auxiliary elevator controller 42. The auxiliary elevator controller 42 is designed so that it may conceive by the signal from the temperature sensor 41 that the temperature of the clamp 13 has risen to the predetermined temperature or more. Accordingly, in case the temperature of the clamp 13 has risen to the predetermined temperature or more, the cylinder 17 is driven so that, as shown in FIG. 12B, the clamp 13 may be elevated. As a result, the clamp 13 is separated from the susceptor 9; the temperature of the clamp 13 descends to the predetermined temperature. In case the temperature of the clamp 13 descends lower than the predetermined temperature, the auxiliary elevator controller 42 controls the drive of the cylinder 17 so that, as shown in FIG. 12C, the clamp 13 may descend to the clamp heating position (III). When the clamp 13 descends to the clamp heating position (III) and comes into contact with the susceptor 9, the clamp 13 is heated again.

By repeating the aforementioned operations, the temperature of the clamp 13 may be maintained at the predetermined temperature (step 9c). After the clamp 13 is heated to the predetermined temperature, the predetermined operations are carried out; a second wafer W, on which the thin film is not deposited, is transferred in the treatment chamber 2; and a thin film is deposited on the wafer W ((step 10c) to (step 15c)).

Thereafter, the aforementioned steps ((step 5c) to (step 15c)) are repeated, thereby thin films are successively deposited one at a time on the treatment surfaces of n pieces, in total, of the wafers W.

Thus, in the present implementation mode, the temperature sensor 41 is connected to the clamp 13 to detect the temperature of the clamp 13, and on the basis of the detected temperature, the drive of the cylinder 17 is controlled. Accordingly, the clamp 13 may be maintained at the predetermined temperature.

(Fourth Implementation Mode)

In the following, the fourth implementation mode of the present invention will be explained.

In the present embodiment, an example, where a bottom surface of the clamp is formed planar, that is, the contact projections are not formed on the bottom surface of the clamp, will be explained.

FIG. 13 is a schematic vertical sectional view showing, in enlargement, a periphery portion of a clamp according to the present implementation mode.

As shown in FIG. 13, a clamp 51 of the present implementation mode does not have the contact projection 22 and is formed planar. The clamp 51 comes into contact in plane with the susceptor 9. Since the clamp 51 is formed planar, a problem in that the film thickness of the periphery of the wafer W becomes thinner may be inhibited from occurring. As a result, the thin film may be uniformly formed on the treatment surface of the wafer W.

Furthermore, in the present implementation mode, there is no need of supplying the inert gas from the bottom portion of the treatment chamber 2 to the upper portion thereof. The reason for there being no need of supplying the inert gas from the bottom of the treatment chamber 2 is that in case, for instance, a titanium nitride thin film is formed, even when the processing gas enters between the wafer W and the clamp 51; titanium nitride sticks a little on a side surface and back surface of the wafer W, problems of contamination are not caused.

Thus, in the present implementation mode, since the clamp 51 is formed planar, the thin film may be uniformly deposited on the treatment surface of the wafer W.

(Embodiment 2)

In the following, an embodiment of the present invention will be explained.

By use of the CVD apparatus explained in the aforementioned fourth implementation mode, the time until the temperature of the wafer stabilizes is measured.

In the following, measurement conditions will be explained.

First, the processing gas is supplied into the treatment chamber of the CVD apparatus for 1 min, and thereby a thin film of titanium nitride is formed on the treatment surface of the wafer disposed on the susceptor.

Next, by means of the not shown arm, the wafer, on which the titanium nitride thin film has been deposited, is transferred out of, and the wafer, on which the titanium nitride thin film is not deposited, is transferred into the treatment chamber. For 1 min during the above operations, the clamp is lowered to the clamp heating position (III) and heated to 600° C.

Thereafter, the clamp is elevated to the wafer transfer position (I) and the wafer is disposed. Thereafter, the clamp is lowered to the wafer processing position (II) and the wafer is heated to 600° C. In this state, the time until the temperature of the wafer stabilizes is measured.

Measurement results will be explained in the following.

While the existing CVD apparatus takes substantially several minutes until the temperature of the wafer stabilizes, the CVD apparatus according to the present embodiment may shorten the time until the temperature of the wafer stabilizes to within 1 minute. Accordingly, it is confirmed that the CVD apparatus according to the present implementation mode is shorter in the time until the temperature of the wafer stabilizes than that in the existing CVD apparatus.

(Fifth Implementation Mode)

In the following, the fifth implementation mode of the present invention will be explained.

In the present implementation mode, an example, where in place of the resistance heating-element, a heating lamp is disposed outside of the treatment chamber, and the heating lamp heats the susceptor and the clamp in contact with the susceptor, will be explained.

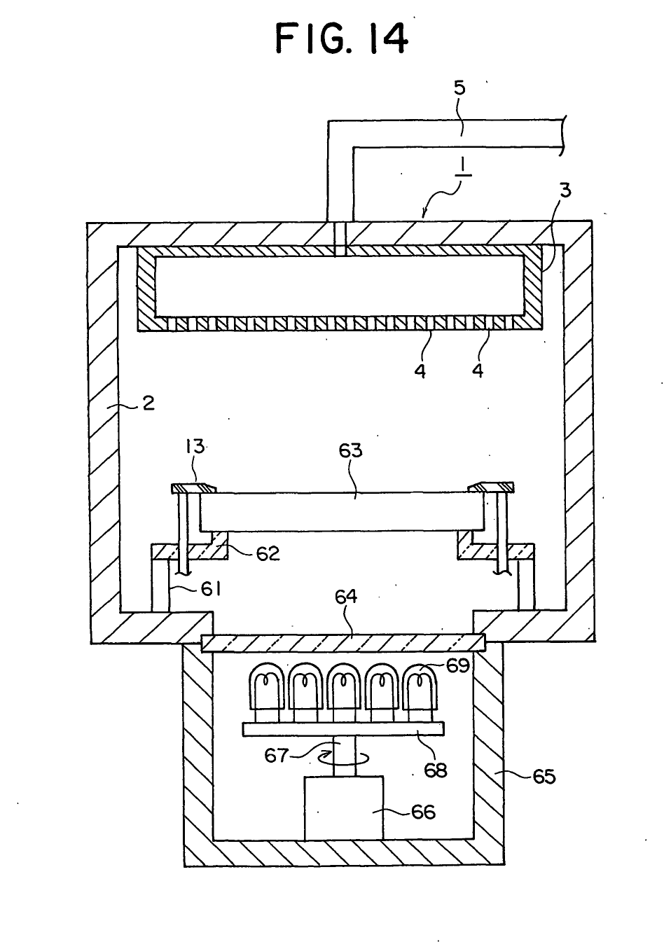

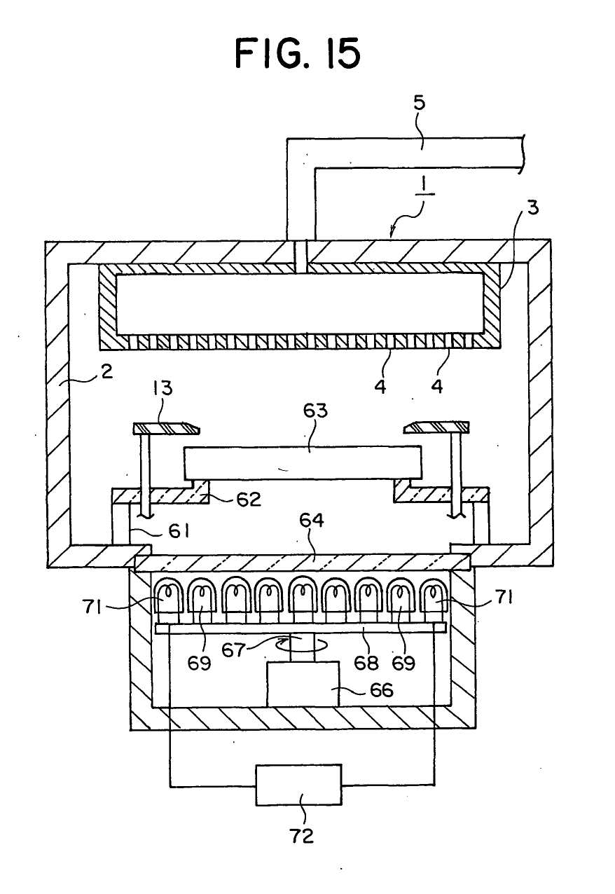

FIG. 14 is a schematic vertical sectional view of a CVD apparatus according to the present implementation mode.

As shown in FIG. 14, in the treatment chamber 2 of the CVD apparatus 1 according to the present implementation mode, at the bottom thereof, a substantially cylindrical supporter 61, made of material transparent to heat-rays, such as, for instance, quartz, is disposed. On the supporter 61, a holding member 62, made of material transparent to heat-rays and formed in substantially L-shape in its section, is disposed. The holding member 62 supports the susceptor 63. Inside of the susceptor 63, the resistance heating-element is not disposed.

In the treatment chamber 2 immediately below the susceptor 63, an opening is formed, and in the opening, a transparent window 64, made of material transparent to heat-rays, such as, for instance, quartz, is fitted in. Below the transparent window 64, a box-like heating chamber 65 is disposed so as to surround the transparent window 64. Inside of the heating chamber 65, a freely rotatable motor 66, a planar turntable 68 held substantially level through an axis of rotation 67 and a heating lamp 69 attached to an top surface of the turntable 68 are disposed. By turning on the heating lamp 69, the clamp 13 is heated to the predetermined temperature.

That is, the heat-rays generated due to the turning on of the heating lamp 69 transmit the transparent window 64, reach the bottom surface of the susceptor 63, thereby the susceptor 63 is heated to a predetermined temperature. As a result, the clamp 13 in contact with the susceptor 63 is heated to a predetermined temperature. While the heating lamp 69 is turned on, in order to make the temperature of the susceptor 63 uniform, the motor 66 is driven so that the entire turntable 68, to which the heating lamp 69 is attached, may be rotated.

Thus, in the present implementation mode, since the heating lamp 69 is disposed outside of the treatment chamber 2, the heating lamp 69 may expedite the temperature rise speed of the susceptor 63 and the clamp 13. As a result, the clamp 13 reaches faster the predetermined temperature.

(Sixth Implementation Mode)

In the following, the sixth implementation mode of the present invention will be explained.

In the present implementation mode, an example where a heating lamp for heating the clamp is disposed will be explained.

FIG. 15 is a schematic vertical sectional view of a CVD apparatus according to the sixth implementation mode.

As shown in FIG. 15, a heating lamp 71 for heating the clamp 13 is disposed outside of the treatment chamber 2 of the CVD apparatus 1 according to the present implementation mode. The heating lamp 71 is preferably disposed immediately below the clamp 13.

A heating lamp controller 72 is electrically connected to the heating lamp 71. The heating lamp controller 72 controls the heating lamp 71 so that the clamp 13 may be heated by the heating lamp 71 while the wafer W, on which the thin film has been deposited, is transferred out of the treatment chamber 2 and the wafer W, on which the thin film is not deposited, is transferred into the treatment chamber 2. When the heating lamp 71 heats the clamp 13, the clamp 13 may be heated without coming into contact with the susceptor 63.

Thus, in the present implementation mode, since the heating lamp 71 for heating the clamp 13 is disposed, the temperature rise speed of the clamp 13 may be expedited. As a result, the clamp 13 may faster reach the predetermined temperature.

The present invention is not restricted to disclosures in the aforementioned first to sixth implementation modes, and structures, materials and arrangements of various members may be appropriately altered within the scope of not departing from the gist of the present invention. For instance, in the first to sixth implementation modes, the CVD apparatus 1 is used as the processing apparatus. However, any processing apparatus that may heat and treat the wafer W, such as an etching apparatus and a PVD (Physical Vapor Deposition) apparatus, may be used. In the first to sixth implementation modes, the wafer is treated one at a time, however, a plurality of the wafers may be simultaneously treated. In the present first to sixth implementation modes, the wafer W is used as the substrate, however, a glass substrate for LCDs may be used.

In the aforementioned second implementation mode, the heat generation amount of the resistance heating-element 10 in the susceptor 9 is controlled by the input voltage of the resistance heating-element 10. However, the power source of the resistance heating-element 10 may be controlled by intermittently turning off and on.

In the fourth implementation mode, although the case where the titanium nitride thin film is deposited on the treatment surface of the wafer W is explained, any material that does not cause inconvenience of contamination when a little bit thereof sticks on the side surface and the back surface of wafer W may be used.

1. A processing method comprising:
transferring a first substrate into a treatment chamber and disposing the first substrate on a susceptor in the treatment chamber;
holding the first substrate disposed on the susceptor by means of a clamp;
applying treatment on the first substrate held by the clamp;
separating the clamp from the treated first substrate;
transferring out the first substrate from the treatment chamber;
heating the clamp while the treated first substrate is transferred out of the treatment chamber and a second substrate, on which the treatment is not applied, is transferred into the treatment chamber;
transferring the second substrate into the treatment chamber and disposing the second substrate on the susceptor in the treatment chamber;
holding the second substrate disposed on the susceptor by the clamp; and
treating the second substrate held by the clamp.

2. A processing method as set forth in claim 1:
wherein the heating of the clamp is implemented based on a detected temperature of the clamp.

3. The processing method as set forth in claim 1:
wherein the second substrate is one piece.

4. The processing method as set forth in claim 1:
wherein the clamp is heated by bringing the clamp into contact with the heated susceptor.

5. The processing method as set forth in claim 1:
wherein the clamp is heated by means of a heating lamp disposed outside of the treatment chamber.

6. The processing method as set forth in claim 1:
wherein the clamp is heated until the clamp is maintained at a temperature 30° C. lower or more with respect to a treatment temperature of the substrate.

7. A processing apparatus, comprising:
a treatment chamber;
a susceptor for disposing a substrate in the treatment chamber;
a clamp movable in an up and down direction for holding the substrate on the susceptor;
a driver for moving the clamp in an up and down direction;
a heating portion for heating the susceptor;
a processing gas introducing system for introducing a processing gas into the treatment chamber; and
a driver controller for controlling the driver so that the clamp comes into contact with the susceptor while the treated substrate is transferred out of the treatment chamber and an untreated substrate is transferred into the treatment chamber.

8. A processing apparatus, comprising:
a treatment chamber;
a susceptor for disposing a substrate in the treatment chamber;
a clamp movable in an up and down direction for holding the substrate on the susceptor;
a driver for moving the clamp in an up and down direction;
a heating lamp that is disposed outside of the treatment chamber and heats the clamp;
a processing gas introducing system for introducing a processing gas into the treatment chamber; and
a heating lamp controller for controlling the heating lamp so that the clamp is heated by the heating lamp while the treated substrate is transferred out of the treatment chamber and an untreated substrate is transferred into the treatment chamber.

9. The processing apparatus as set forth in claim 7, further comprising:
a temperature sensor for detecting a temperature of the clamp; and
a heater controller for controlling the heater portion while a treated substrate is transferred out of the treatment chamber and an untreated substrate is transferred into the treatment chamber, based on the temperature of the clamp detected by the temperature sensor.

10. The processing apparatus as set forth in claim 7, further comprising:
a temperature sensor for detecting a temperature of the clamp; and
an auxiliary driver controller for controlling the driver while the treated substrate is transferred out of the treatment chamber and the untreated substrate is transferred into the treatment chamber, based on the temperature of the clamp detected by the temperature sensor.
